(19) United States
(12) Patent Application Publication
(10) Pub. No.: US 2026/0059945 A1
(43) Pub. Date: Feb. 26, 2026

(54) DISPLAY APPARATUS AND ELECTRONIC DEVICE INCLUDING THE SAME

(71) Applicant: Samsung Display Co., Ltd., Yongin-Si (KR)

(72) Inventors: Minyeul Ryu, Yongin-si (KR); Daesoo Kim, Yongin-si (KR); Jongmin Lee, Yongin-si (KR); Jun Heo, Yongin-si (KR)

(21) Appl. No.: 19/301,316

(22) Filed: Aug. 15, 2025

(30) Foreign Application Priority Data
Aug. 22, 2024 (KR) 10-2024-0113096

(51) Int. Cl. H10K 59/122

(52) U.S. Cl. CPC H10K 59/122

(57) ABSTRACT

Provided are a display apparatus in which a defect rate is reduced and an electronic device including the same. The display apparatus includes a substrate, a first pixel electrode and a second pixel electrode, which are disposed on the substrate, a pixel-defining layer disposed on the substrate and covering edges of the first pixel electrode and second pixel electrode, and a spacer disposed on the pixel-defining layer and provided between the first pixel electrode and the second pixel electrode in a plan view. The pixel-defining layer includes at least one trench provided between the spacer and the first pixel electrode in a plan view and an angle between an inner surface of the at least one trench and a bottom surface of the at least one trench is more than 90°.

### CROSS-REFERENCE TO RELATED APPLICATION

This application is based on and claims priority under 35 U.S.C. § 119 to Korean Patent Application No. 10-2024-0113096, filed on Aug. 22, 2024, in the Korean Intellectual Property Office, the disclosure of which is incorporated by reference herein in its entirety.

### BACKGROUND

### 1. Field

One or more embodiments relate to a display apparatus and an electronic device including the same, and more particularly, to a display apparatus in which a defect rate is reduced, and an electronic device including the same.

### 2. Description of the Related Art

A display apparatus receives information about an image and displays the image. The display apparatus may be used as a display of a small product such as a mobile phone, or may be used as a display of a large product such as a television.

To externally display the image, the display apparatus includes a plurality of pixels that emit light by receiving an electrical signal. Each pixel includes a light-emitting element, and for example, in a case of an organic light-emitting display apparatus, an organic light-emitting diode (OLED) is provided as a light-emitting element. Generally, an organic light-emitting display apparatus includes a thin-film transistor and an OLED on a substrate, and the OLED self-emits light.

An electronic device performs various functions and may include the above-described display apparatus.

### SUMMARY

One or more embodiments include a display apparatus in which a defect rate is reduced, and an electronic device including the same.

Additional aspects will be set forth in part in the description which follows and, in part, will be apparent from the description, or may be learned by practice of the presented embodiments of the disclosure.

According to one or more embodiments, a display apparatus includes a substrate, a first pixel electrode and a second pixel electrode, which are disposed on the substrate, a pixel-defining layer disposed on the substrate and covering edges of the first pixel electrode and second pixel electrode, and a spacer disposed on the pixel-defining layer and provided between the first pixel electrode and the second pixel electrode in a plan view. The pixel-defining layer includes at least one trench provided between the spacer and the first pixel electrode in a plan view and an angle between an inner surface of the at least one trench and a bottom surface of the at least one trench is more than 90°.

According to an embodiment, the pixel-defining layer may include a first trench adjacent to the spacer and a second trench provided between the first pixel electrode and the first trench.

According to an embodiment, a distance between a bottom surface of the first trench and a bottom surface of the pixel-defining layer may be greater than a distance between a bottom surface of the second trench and the bottom surface of the pixel-defining layer.

According to an embodiment, the pixel-defining layer may further include a third trench provided between the second trench and the first pixel electrode in a plan view.

According to an embodiment, a distance between a bottom surface of the second trench and a bottom surface of the pixel-defining layer may be greater than a distance between a bottom surface of the third trench and the bottom surface of the pixel-defining layer.

According to an embodiment, the first trench may surround, in a shape of “□”, the spacer in a plan view.

According to an embodiment, the second trench may surround, in a shape of “□”, the first trench in a plan view.

According to an embodiment, the pixel-defining layer may further include a third trench provided between the second trench and the first pixel electrode, and a third′ trench provided between the second trench and the second pixel electrode, in a plan view.

According to an embodiment, the first pixel electrode and the second pixel electrode may be spaced apart from each other in a first direction in a plan view.

According to an embodiment, at least a portion of the at least one trench may extend in a second direction crossing the first direction in a plan view.

According to one or more embodiments, a display apparatus includes a substrate, a first pixel electrode and a second pixel electrode, which are disposed on the substrate, a pixel-defining layer disposed on the substrate and covering edges of the first pixel electrode and second pixel electrode, a spacer disposed on the pixel-defining layer and provided between the first pixel electrode and the second pixel electrode in a plan view, and at least one protrusion disposed on the pixel-defining layer and arranged around the spacer in a plan view. The at least one protrusion is provided between the spacer and the first pixel electrode in a plan view and an angle between an outer surface of the at least one protrusion and a top surface of the substrate is more than 90°.

According to an embodiment, the at least one protrusion may include a first protrusion adjacent to the spacer and a second protrusion provided between the first pixel electrode and the first protrusion.

According to an embodiment, a thickness of the pixel-defining layer may decrease towards the first pixel electrode away from the spacer.

According to an embodiment, the at least one protrusion may further include a third protrusion provided between the second protrusion and the first pixel electrode in a plan view.

According to an embodiment, the first protrusion may surround, in a shape of “□”, the spacer in a plan view.

According to an embodiment, the second protrusion may surround, in a shape of “□”, the first protrusion in a plan view.

According to an embodiment, the at least one protrusion may further include a third′ protrusion provided between the second protrusion and the second pixel electrode in a plan view.

According to an embodiment, the first pixel electrode and the second pixel electrode may be spaced apart from each other in a first direction in a plan view.

According to an embodiment, at least a portion of the at least one protrusion may extend in a second direction crossing the first direction in a plan view.

According to one or more embodiments, an electronic device includes a memory storing instructions, a processor configured to operate the instructions to generate a control command, and a display apparatus configured to display an image based on the control command. The display apparatus includes a substrate, a first pixel electrode and a second pixel electrode, which are disposed on the substrate, a pixel-defining layer disposed on the substrate and covering edges of the first pixel electrode and second pixel electrode, and a spacer disposed on the pixel-defining layer and provided between the first pixel electrode and the second pixel electrode in a plan view. The pixel-defining layer includes at least one trench provided between the spacer and the first pixel electrode in a plan view and an angle between an inner surface of the at least one trench and a bottom surface of the at least one trench is more than 90°.

### BRIEF DESCRIPTION OF THE DRAWINGS

The above and other aspects, features, and advantages of certain embodiments of the disclosure will be more apparent from the following description taken in conjunction with the accompanying drawings.

FIG. 1 is a plan view schematically showing a display apparatus according to an embodiment.

FIG. 2 is a cross-sectional view of the display apparatus taken along line A-A′ of FIG. 1, according to an embodiment.

FIG. 3 is a cross-sectional view of the display apparatus taken along line B-B′ of FIG. 1, according to an embodiment.

FIG. 4 is a cross-sectional view of a region C of FIG. 3, according to an embodiment.

FIG. 5 is a cross-sectional view of the region C of FIG. 3, according to an embodiment.

FIG. 6 is a cross-sectional view of a region C of FIG. 3, according to an embodiment.

FIG. 7 is a plan view schematically showing a display apparatus according to an embodiment.

FIG. 8 is a cross-sectional view of the display apparatus taken along line I-I′ of FIG. 7, according to an embodiment.

FIG. 9 is a plan view schematically showing a display apparatus according to an embodiment.

FIG. 10 is a cross-sectional view of the display apparatus taken along line II-II′ of FIG. 9, according to an embodiment.

FIG. 11 is a plan view schematically showing a display apparatus according to an embodiment.

FIG. 12 is a cross-sectional view of the display apparatus taken along line III-III′ of FIG. 11, according to an embodiment.

FIG. 13 is a plan view schematically showing a display apparatus according to Comparative Example.

FIG. 14 is a cross-sectional view of the display apparatus taken along line IV-IV′ of FIG. 13.

FIG. 15 is a conceptual view schematically showing an electronic device including the display apparatus of FIG. 1.

### DETAILED DESCRIPTION

The disclosure may have various modifications and various embodiments, and specific embodiments are illustrated in the drawings and are described in detail in the detailed description. Effects and features of the disclosure and methods of achieving the same will become apparent with reference to embodiments described in detail with reference to the drawings. However, the disclosure is not limited to the embodiments described below, and may be implemented in various forms.

Hereinafter, embodiments will be described in detail with reference to the accompanying drawings, and in the following description with reference to the drawings, like reference numerals refer to like components and redundant descriptions thereof will be omitted.

In the following embodiments, the terms “first” and “second” are not used in a limited sense and are used to distinguish one component from another component. In the following embodiments, an expression used in the singular encompasses the expression of the plural, unless it has a clearly different meaning in the context.

It will be understood that when a layer, region, or component is referred to as being “formed on,” another layer, region, or component, it can be directly or indirectly formed on the other layer, region, or component. That is, for example, intervening layers, regions, or components may be present.

Sizes of elements in the drawings may be exaggerated for convenience of explanation. In other words, because sizes and thicknesses of components in the drawings are arbitrarily illustrated for convenience of explanation, the disclosure is not necessarily limited thereto.

In the following embodiments, it will be further understood that the terms “comprise” and/or “comprising” used herein specify the presence of stated features or components, but do not preclude the presence or addition of one or more other features or components.

It will be understood that when a layer, region, or element is referred to as being “formed on” another layer, area, or element, it can be directly or indirectly formed on the other layer, region, or element. That is, for example, intervening layers, regions, or elements may be present.

When a certain embodiment may be implemented differently, a specific process order may be performed differently from the described order. For example, two consecutively described processes may be performed substantially at the same time or performed in an order opposite to the described order.

In the specification, “A and/or B” denotes only A, only B, or both A and B. Also, “at least one of A and B”denotes only A, only B, or both A and B.

When a layer, region, component, or the like is connected to another layer, region, component, or the like, the layer, the region, the component, or the like may be directly connected thereto and/or may be indirectly connected thereto with an intervening layer, region, component, or the like therebetween. For example, in the specification, when a layer, region, component, or the like is electrically connected to another layer, region, component, or the like, the layer, region, component, or the like may be directly electrically connected thereto and/or may be indirectly electrically connected thereto with an intervening layer, region, component, or the like therebetween.

According to embodiments, an x-axis, a y-axis, and a z-axis are not limited to three axes on an orthogonal coordinate system, but may be interpreted in a broad sense including the three axes. For example, the x-axis, the y-axis, and the z-axis may be perpendicular to one another, or may represent different directions that are not perpendicular to one another.

Hereinafter, a display apparatus and an electronic device including the same, according to an embodiment will be described in detail, based on the above descriptions.

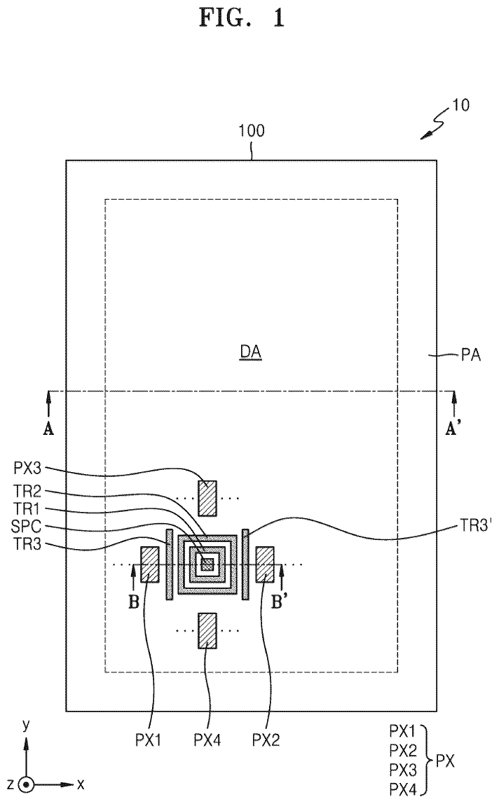

FIG. 1 is a plan view schematically showing a display apparatus according to an embodiment.

As shown in FIG. 1, the display apparatus according to the present embodiment includes a display panel 10. The display apparatus is not limited as long as the display apparatus includes the display panel 10.

The display apparatus is an apparatus for displaying a moving image or a still image, and may be used as a display screen of not only portable electronic devices, such as mobile phones, smartphones, tablet personal computers (PCs), mobile communication terminals, electronic notebooks, electronic books, portable multimedia players (PMPs), navigation devices, and ultra-mobile PCs (UMPCs), but also various products, such as televisions, laptop computers, monitors, billboards, and Internet of things (IoT).

The display apparatus according to an embodiment may be used for wearable devices, such as smart watches, watch phones, glasses-type displays, and head mounted displays (HMDs).

The display apparatus according to an embodiment may be used as a panel of a vehicle, a center information display (CID) arranged on a center fascia or dashboard of a vehicle, a room mirror display replacing a side mirror of a vehicle, or a display arranged on a rear surface of a front seat, as entertainment for a back seat of a vehicle.

The display panel 10 includes a display area DA and a peripheral area PA outside the display area DA. The display area DA is a portion in which an image is displayed, and a plurality of pixels PX may be arranged in the display area DA. When viewed in a direction approximately perpendicular to the display panel 10, the display area DA may have any one of various shapes, such as a circle, an oval, a polygon, and a specific figure. In FIG. 1, the display area DA has an approximately rectangular shape in which corners are round.

The peripheral area PA may be arranged outside the display area DA. The peripheral area PA is an area in which an image is not displayed and may surround the display area DA.

The display area DA is a portion in which an image is displayed and may include the plurality of pixels PX. Each pixel PX may include a display element such as an organic light-emitting element. Each pixel P may emit, for example, red, green, or blue light. Such a pixel PX may be connected to a pixel circuit including a thin-film transistor (TFT), a storage capacitor, and the like. The pixel circuit may be connected to a scan line (not shown) configured to transmit a scan signal, a data line (not shown) crossing the scan line and configured to transmit a data signal, and a driving voltage line (not shown) configured to supply a driving voltage. The data line and the driving voltage line may extend in a y-axis direction and the scan line may extend in an x-axis direction.

The pixel PX may emit light of luminance corresponding to an electrical signal from the pixel PX that is electrically connected to the pixel PX. The display area DA may display a certain image through light emitted from the pixel PX. For reference, the pixel PX may be defined as a component configured to emit light of any one color from among red, green, and blue, or a component required to emit light of any one color from among red, green, and blue.

The peripheral area PA is an area in which the pixel PX is not arranged, and thus may be an area in which an image is not displayed. A power supply wire (not shown) configured to drive the pixel PX and the like may be arranged in the peripheral area PA. Also, pads (not shown) may be arranged in the peripheral area PA, and an integrated circuit device (not shown) such as a printed circuit board including a driving circuit unit (not shown) may be electrically connected to the pads in the peripheral area PA.

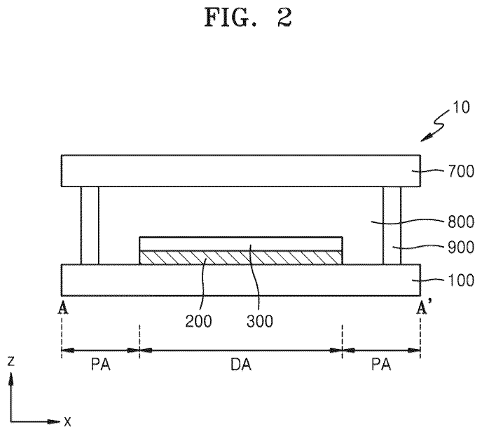

The display panel 10 includes a substrate 100 further described with reference to FIG. 2 and below, and thus, it may be described that the substrate 100 includes the display area DA and the peripheral area PA described above. Hereinafter, for convenience, it is described that the substrate 100 or the display panel 10 includes the display area DA and the peripheral area PA.

Hereinafter, an organic light-emitting display apparatus is described as an example of the display apparatus according to an embodiment, but the display apparatus of the disclosure is not limited thereto. For example, the display apparatus of the disclosure may be an inorganic light-emitting display apparatus or a quantum dot light-emitting display apparatus. For example, an emission layer of a display element included in the display apparatus may include an organic material or an inorganic material. For example, the display apparatus may include an emission layer and a quantum dot layer arranged on a path of light emitted from the emission layer.

According to an embodiment, the pixels PX may include a first pixel PX1, a second pixel PX2, a third pixel PX3, and a fourth pixel PX4. For convenience of description, only some pixels are described, but more pixels may be arranged in the display area DA in any one of various combinations.

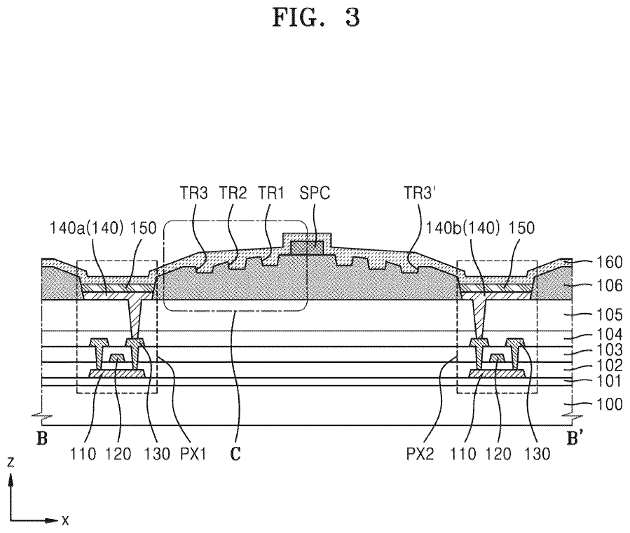

For convenience of description, the pixel PX is illustrated in the form of a rectangle, but the shape of the pixel PX may vary in a plan view. A light-emitting area from which light is emitted may be defined by a pixel-defining layer 106 described with reference to FIG. 3 and below. Descriptions about the pixel PX in the present specification may be descriptions about components included in the pixel PX.

In a plan view, the first pixel PX1 and the second pixel PX2 may be spaced apart from each other in a first direction (e.g., an x-axis direction). The third pixel PX3 and the fourth pixel PX4 may be spaced apart from each other in a second direction (e.g., a y-axis direction) crossing the first direction.

In a plan view, a spacer SPC described below may be arranged between the first pixel PX1 and the second pixel PX2. At least one trench may be arranged based on the spacer SPC and prevent a filler 800 (see FIG. 2) injected according to a crack generated in the spacer SPC from being introduced to the pixel PX around the spacer SPC. The at least one trench may provide a space in which the filler 800 may accumulate, thereby operating as a buffer for preventing the filler 800 from being introduced to the pixel PX around the spacer SPC.

The crack generated in the spacer SPC may be generated when a mask or the like contacts the spacer SPC. In particular, heights of the spacers SPC may be different from each other due to an error, and in this case, the highest spacer SPC may receive excessive force from the mask. Accordingly, the highest spacer SPC from among the spacers SPC may easily crack.

The at least one trench may be provided between the spacer SPC and the first pixel PX1. The at least one trench may be provided between the spacer SPC and the second pixel PX2. The at least one trench may be provided between the spacer SPC and the third pixel PX3. The at least one trench may be provided between the spacer SPC and the fourth pixel PX4. At least one trench may be provided between the spacer SPC and the pixel PX arranged around the spacer SPC.

The at least one trench may denote a concave groove formed in the pixel-defining layer 106, e.g. see FIG. 3. For example, the pixel-defining layer 106 may include at least one trench that is a concave groove formed in a top surface thereof. The at least one trench may be a concave groove formed in the pixel-defining layer 106 according to an etching process (e.g., a dry etching process or a wet etching process). For convenience of description, it may be described that “at least one trench is arranged at a specific location” and description that “at least one trench is arranged at a specific location” may indicate that “at least one trench may be formed at a specific location through an etching process or the like.”

The at least one trench may have a pattern of a pre-set shape. For example, the at least one trench may surround, in the shape of “□”, e.g., a rectangle such as a square or other shape, the spacer SPC or may be arranged between the spacer SPC and the pixel PX in a straight line extending in the first direction or the second direction.

A first trench TR1 may be adjacent to the spacer SPC. The first trench TR1 may be provided between the spacer SPC and the first pixel PX1. For example, it may be understood that the first trench TR1 may surround, in the shape of “□”, the spacer SPC in a plan view and the first trench TR1 may be arranged between the spacer SPC and other pixels PX in a plan view.

A second trench TR2 may be adjacent to the first trench TR1. The second trench TR2 may be provided between the first trench TR1 and the first pixel PX1. For example, it may be understood that the second trench TR2 may surround, in the shape of “□”, the first trench TR1 in a plan view and the second trench TR2 may be arranged between the first trench TR1 and other pixels PX in a plan view.

The third trench TR3 and a third′ trench TR3′ may be adjacent to the second trench TR2. The third trench TR3 may be provided between the second trench TR2 and the first pixel PX1. For example, the third trench TR3 may be formed, in the shape of a straight line (▬), between the second trench TR2 and the first pixel PX1. The third′ trench TR3′ may be provided between the second trench TR2 and the second pixel PX2. For example, the third′ trench TR3′ may be formed, in the shape of a straight line (▬), between the second trench TR2 and the first pixel PX1.

For example, the first pixel PX1 and the second pixel PX2 may be spaced apart from each other in the first direction in a plan view, and at least a portion of the at least one trench may extend in the second direction crossing the first direction in a plan view.

For example, some of the first trench TR1, which is provided between the first pixel PX1 and the spacer SPC, may extend in the second direction. As used herein, some may mean one or more portions of a particular feature such as a trench. Some of the first trench TR1, which is provided between the second pixel PX2 and the spacer SPC, may extend in the second direction. Some of the first trench TR1, which is provided between the third pixel PX3 and the spacer SPC, may extend in the first direction. Some of the first trench TR1, which is provided between the fourth pixel PX4 and the spacer SPC, may extend in the first direction.

For example, some of the second trench TR2, which is provided between the first pixel PX1 and the spacer SPC, may extend in the second direction. Some of the second trench TR2, which is provided between the second pixel PX2 and the spacer SPC, may extend in the second direction. Some of the second trench TR2, which is provided between the third pixel PX3 and the spacer SPC, may extend in the first direction. Some of the second trench TR2, which is provided between the fourth pixel PX4 and the spacer SPC, may extend in the first direction.

For example, the third trench TR3 may extend in the second direction. The third ‘trench TR3’ may extend in the second direction.

FIG. 2 is a cross-sectional view of the display apparatus taken along line A-A′ of FIG. 1, according to an embodiment.

For convenience of description, while describing FIG. 2, details that are the same as or overlap those above may be omitted.

As shown in FIG. 2, the display apparatus may include the substrate 100, a display layer 200 on the substrate 100, and an upper layer 300 on the display layer 200.

As described above, the substrate 100 may include areas corresponding to the display area DA and the peripheral area PA outside the display area DA. The substrate 100 may include various flexible or bendable materials. For example, the substrate 100 may include glass, a metal, or a polymer resin. The substrate 100 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. Various modifications are possible, for example, the substrate 100 may have a multilayer structure including two layers each including such a polymer resin, and a barrier layer arranged between the layers and including an inorganic material (such as silicon oxide, silicon nitride, or silicon oxynitride).

The display layer 200 may be disposed on the substrate 100. The display layer 200 may include an organic light-emitting diode that is a display element, a pixel circuit electrically connected to the organic light-emitting diode, and insulating layers provided therebetween. The upper layer 300 may be disposed on the display layer 200.

An encapsulation substrate 700 may be arranged above the substrate 100. The encapsulation substrate 700 may include glass or a polymer resin. For example, the polymer resin may include polyether sulfone, polyacrylate, polyether imide, polyethylene naphthalate, polyethylene terephthalate, polyphenylene sulfide, polyarylate, polyimide, polycarbonate, or cellulose acetate propionate. The encapsulation substrate 700 including the polymer resin may be flexible, rollable, or bendable. The encapsulation substrate 700 may have a multilayer structure including a layer including the polymer resin and an inorganic layer (not shown).

The substrate 100 and the encapsulation substrate 700 may be connected to each other through a sealing member 900. The sealing member 900 may be arranged in the peripheral area PA to surround the display area DA. For example, in a plan view, the sealing member 900 may be arranged outside the display area DA and form a closed loop. In this case, the sealing member 900 may completely block the display area DA from the outside. Such a sealing member 900 may include sealant, frit, or the like. According to an embodiment, the filler 800 may be provided in a gap between the substrate 100 and the encapsulation substrate 700.

As shown in FIGS. 1 and 2, by arranging the at least one trench around the spacer SPC, the display apparatus according to an embodiment may effectively block the filler 800 introduced through a crack that may be generated in the spacer SPC. Accordingly, introduction of the filler 800 to a pixel region may be prevented, thereby preventing display quality deterioration.

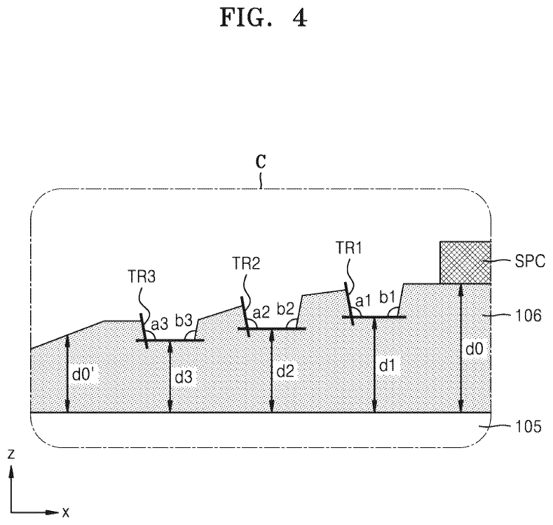

FIG. 3 is a cross-sectional view of the display apparatus taken along line B-B′ of FIG. 1, according to an embodiment, and FIG. 4 is a cross-sectional view of a region C of FIG. 3, according to an embodiment.

For convenience of description, while describing FIGS. 3 and 4, details that are the same as or overlap those above may be omitted. The display layer 200 in the present specification may include layers from a buffer layer 101 described below to an opposing electrode 160 described below. The upper layer 300 may include a thin-film encapsulation layer (not shown) described below and a touch sensing layer (not shown) disposed on the thin-film encapsulation layer.

The buffer layer 101 may be disposed on the substrate 100. The buffer layer 101 may operate as a barrier layer and/or a blocking layer to prevent diffusion of impurity ions, prevent penetration of moisture or external air, and flatten a surface. The buffer layer 101 may include silicon oxide, silicon nitride, or silicon oxynitride. In addition, the buffer layer 101 may adjust a rate at which heat is provided during a crystallization process for forming a semiconductor layer 110 such that the semiconductor layer 110 may be uniformly crystallized.

The semiconductor layer 110 may be disposed on the buffer layer 101. The semiconductor layer 110 may include polysilicon, and may include a channel region in which impurities are not doped, and a source region and a drain region arranged on both sides of the channel region and in which impurities are doped. Here, the impurities may vary according to the type of thin film transistor (TFT), and may be N-type impurities or P-type impurities.

A gate insulating layer 102 may be disposed on the semiconductor layer 110. The gate insulating layer 102 may be a component securing insulation between the semiconductor layer 110 and a gate layer 120. The gate insulating layer 102 may include an inorganic material such as silicon oxide, silicon nitride, and/or silicon oxynitride, and may be provided between the semiconductor layer 110 and the gate layer 120. Also, the gate insulating layer 102 has a shape corresponding to an entire surface of the substrate 100 and may have a structure in which contact holes are formed in a pre-set portion. An insulating layer including an inorganic material as such may be formed through chemical vapor deposition (CVD) or atomic layer deposition (ALD). This is also applied to embodiments described below and modifications thereof.

The gate layer 120 may be disposed on the gate insulating layer 102. The gate layer 120 may be arranged at locations overlapping the semiconductor layer 110 on and below, and may include at least one metal from among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (Cu).

An interlayer insulating layer 103 may be disposed on the gate layer 120. The interlayer insulating layer 103 may cover the gate layer 120. The interlayer insulating layer 103 may include an inorganic material. For example, the interlayer insulating layer 103 may include a metal oxide or a metal nitride, and in detail, the inorganic material may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). According to some embodiments, the interlayer insulating layer 103 may have a double structure of SiOₓ/SiN_{y} or SiNₓ/SiO_{y}.

A first conductive layer 130 may be arranged on the interlayer insulating layer 103. The first conductive layer 130 may operate as an electrode connected to the source/drain region of a semiconductor layer, through a via hole in the interlayer insulating layer 103. The first conductive layer 130 may include one or more metals selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the first conductive layer 130 may include a Ti layer, an Al layer, and/or a Cu layer.

A first organic insulating layer 104 may be disposed on the first conductive layer 130. The first organic insulating layer 104 may be an organic insulating layer that covers a top portion of the first conductive layer 130 and has an approximately flat top surface, thereby operating as a planarization layer. The first organic insulating layer 104 may include an organic material, for example, acryl, benzocyclobutene (BCB), or hexamethyldisiloxane (HMDSO). The first organic insulating layer 104 may be variously modified, such as being configured as a single layer or a multilayer.

A second conductive layer (not shown) may be arranged on the first organic insulating layer 104. The second conductive layer may operate as an electrode connected to the source/drain region of the semiconductor layer, through a via hole in the first organic insulating layer 104. The second conductive layer may include one or more metals selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the second conductive layer may include a Ti layer, an Al layer, and/or a Cu layer.

A second organic insulating layer 105 may be disposed on the second conductive layer or the first organic insulating layer 104. The second organic insulating layer 105 may be an organic insulating layer that covers a top portion of the second conductive layer or the first organic insulating layer 104 and has an approximately flat top surface, thereby operating as a planarization layer. The second organic insulating layer 105 may include an organic material, for example, acryl, benzocyclobutene (BCB), or hexamethyldisiloxane (HMDSO). The second organic insulating layer 105 may be variously modified, such as being configured as a single layer or a multilayer.

A pixel electrode 140 may be disposed on the second organic insulating layer 105. The pixel electrode 140 may be connected to the first conductive layer 130 or the second conductive layer through a contact hole formed in the second organic insulating layer 105. display element may be disposed on the pixel electrode 140. An organic light-emitting diode may be used as the display element. In other words, the organic light-emitting diode may be disposed on, for example, the pixel electrode 140. The pixel electrode 140 may include a light-transmitting conductive layer including a light-transmitting conductive oxide such as indium tin oxide (ITO), indium oxide (In₂O₃), or indium zinc oxide (IZO), and a reflective layer including a metal such as Al or Ag. For example, the pixel electrode 140 may have a three-layer structure of ITO/Ag/ITO.

For example, the pixel electrode 140 may include a first pixel electrode 140a included in the first pixel PX1 of FIG. 1. The pixel electrode 140 may include a second pixel electrode 140b included in the second pixel PX2 of FIG. 1. The pixel electrode 140 may include a third pixel electrode (not shown) included in the third pixel PX3 of FIG. 1. The pixel electrode 140 may include a fourth pixel electrode (not shown) included in the fourth pixel PX4 of FIG. 1. In addition, the pixel electrode 140 may further include other pixel electrodes included in pixels other than the first pixel PX1 to the fourth pixel PX4.

The pixel-defining layer 106 may be disposed on the second organic insulating layer 105 and arranged to cover an edge of the pixel electrode 140. In other words, the pixel-defining layer 106 may cover the edge of the pixel electrode 140. The pixel-defining layer 106 includes an opening corresponding to the pixel PX, and the opening may be formed such that at least a center portion of the pixel electrode 140 is exposed. Such a pixel-defining layer 106 may include an organic material, for example, polyimide or HMDSO. Also, the spacer SPC may be disposed on the pixel-defining layer 106.

The spacer SPC may be arranged in the peripheral area PA and/or the display area DA. The spacer SPC may prevent other components from being damaged by sagging of the mask during a manufacturing process using the mask. The spacer SPC includes an organic insulating material and may be formed as a single layer or a multilayer.

An intermediate layer 150 and the opposing electrode 160 may be disposed on the opening of the pixel-defining layer 106. The intermediate layer 150 may include a low-molecular weight material or a high-molecular weight material. When the intermediate layer 150 includes the low-molecular weight material, the intermediate layer 150 may include a hole injection layer, a hole transport layer, an emission layer, an electron transport layer, and/or an electron injection layer. When the intermediate layer 150 includes the high-molecular weight material, the intermediate layer 150 may usually have a structure including a hole transport layer and an emission layer.

The opposing electrode 160 may include a light-transmitting conductive layer including a light-transmitting conductive oxide, such as ITO, In₂O₃, or IZO. The pixel electrode 140 may be used as an anode and the opposing electrode 160 may be used as a cathode. Polarities of electrodes may be switched.

A structure of the intermediate layer 150 is not limited thereto and may vary. For example, at least one of layers included in the intermediate layer 150 may be integrated with the opposing electrode 160. For example, the intermediate layer 150 may include a layer patterned to correspond to each of the pixel electrodes 140.

The opposing electrode 160 may be arranged on the display area DA and provided throughout the display area DA. In other words, the opposing electrode 160 may be integrally formed to cover the plurality of pixels PX. The opposing electrode 160 may be in electrical contact with a common power supply line (not shown) arranged in the peripheral area PA. According to an embodiment, the opposing electrode 160 may extend up to a barrier wall (not shown).

According to an embodiment, the pixel-defining layer 106 may be disposed on the substrate 100 and cover edges of the first pixel electrode 140a and the second pixel electrode 140b. The pixel-defining layer 106 may include at least one trench provided between the spacer SPC and the first pixel electrode 140a in a plan view. Angles a1 to a3 and b1 to b3 between an inner surface of the at least one trench and a bottom surface of the at least one trench (or the top surface of the substrate 100) may be more than 90°. Here, the angles a1, a2, a3, b1, b2, and b3 between the inner surface of the at least one trench and the bottom surface of the at least one trench (or the top surface of the substrate 100) may be an angle measured inside the trench.

For example, the inner surface of the at least one trench may be divided into a first portion farther away from the spacer SPC and a second portion closer to the spacer SPC. For example, the angles a1, a2, and a3 between the first portion and the bottom surface of the at least one trench (or the top surface of the substrate 100) may be more than 90°. For example, the angles b1, b2, and b3 between the second portion and the bottom surface of the at least one trench (or the top surface of the substrate 100) may be more than 90°.

When the angles a1, a2, a3, b1, b2, and b3 between the inner surface of the at least one trench and the bottom surface of the at least one trench (or the top surface of the substrate 100) are more than 90°, the following effects may be achieved.
The filler 800 leaked through a crack generated in the spacer SPC may be trapped in the trench.
According to the trench including the inner surface having a gentle slope, only a certain volume of the filler 800 may be trapped in the trench and the remaining volume may flow to another trench.
When the trench includes the inner surface having a rapid slope, more than a certain volume of the filler 800 may be trapped in the trench, thereby generating adverse effects. The adverse effects generated at this time may indicate a case in which the filler 800 flows through another path.
Accordingly, the inner surface of the trench may have a gentle slope to induce the filler 800 to flow along a desired path and prevent a defect during a warranty period guaranteed by a product.
As such, a feature of the display apparatus according to an embodiment is to delay an introduction speed of the filler 800 rather than completely preventing introduction of the filler 800, and in this regard, may include a structure in which the inner surface of the trench has a gentle slope.
The feature for slowing down the introduction speed of the filler 800 may reduce an occurrence of defects caused by the filler 800 during the warranty period of the display apparatus, thereby increasing reliability and life of a product.

As such, to induce the filler 800 to flow from a previous trench to a next trench, the angles a1, a2, and a3 between the first portion and the bottom surface of the at least one trench (or the top surface of the substrate 100) need to exceed 90°.

For example, the at least one trench shown in FIG. 3 may be a trench formed through a dry etching process.

For example, the at least one trench may include a plurality of trenches. The pixel-defining layer 106 may include the first trench TR1 adjacent to the spacer SPC and the second trench TR2 provided between the first pixel electrode 140a and the first trench TR1. A distance d1 between a bottom surface of the first trench TR1 and a bottom surface of the pixel-defining layer 106 may be greater than a distance d2 between a bottom surface of the second trench TR2 and the bottom surface of the pixel-defining layer 106.

Thicknesses d0 and d0′ of the pixel-defining layer 106 may decrease towards the first pixel electrode 140a, based on the spacer SPC. The thicknesses d0 and d0′ of the pixel-defining layer 106 may decrease towards the second pixel electrode 140b, based on the spacer SPC. The thicknesses d0 and d0′ of the pixel-defining layer 106 may decrease towards the third pixel electrode, based on the spacer SPC. The thicknesses d0 and d0′ of the pixel-defining layer 106 may decrease towards the fourth pixel electrode, based on the spacer SPC. For example, the thicknesses d0 and d0′ of the pixel-defining layer 106 may decrease away from the spacer SPC. The thicknesses d0 and d0′ of the pixel-defining layer 106 are average thicknesses, and the thickness d0 of a region in which the spacer SPC is arranged may be the greatest.

The pixel-defining layer 106 may further include the third trench TR3 provided between the second trench TR2 and the first pixel electrode 140a in a plan view. The distance d2 between the bottom surface of the second trench TR2 and the pixel-defining layer 106 may be greater than a distance d3 between a bottom surface of the third trench TR3 and the pixel-defining layer 106.

For example, the trenches formed in the pixel-defining layer 106 may be arranged closer to a reference surface (the bottom surface of the pixel-defining layer 106 or the top surface of the substrate 100) as the farther away the trenches are from the spacer SPC, based on the bottom surface of the pixel-defining layer 106 or the top surface of the substrate 100. Accordingly, the distance d1 between the bottom surface of the first trench TR1 and the bottom surface of the pixel-defining layer 106 may be the greatest.

The filler 800 may be induced to flow from a previous trench to a next trench according to the distances d1 and d2 and the thicknesses d0 and d0′ of the pixel-defining layer 106. Accordingly, the filler 800 may be prevented from overflowing through an unexpected path.

As shown in FIGS. 3 and 4, introduction of the filler 800 may be blocked in multiple manners by arranging the plurality of trenches (the first trench TR1, the second trench TR2, and the third trench TR3) in stages. Further effective blocking effects may be provided compared to a single trench, and accordingly, a defect rate of the display apparatus may be further decreased.

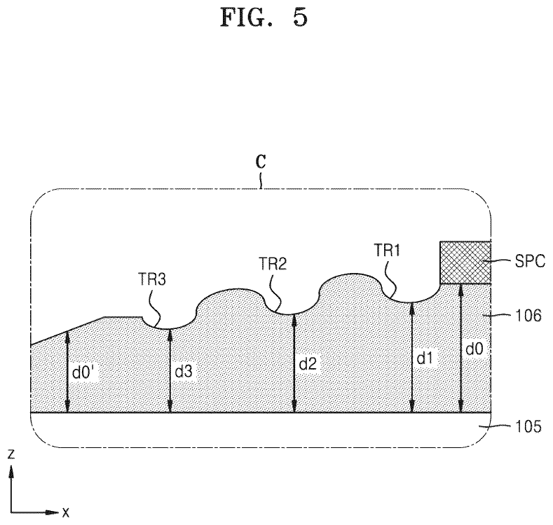

FIG. 5 is a cross-sectional view of the region C of FIG. 3, according to an embodiment.

For reference, while describing FIG. 5, details that are the same as or overlap those above may be omitted. For convenience of description, an example of the region C is described, but in light of this disclosure one of ordinary skill in the art will understand that a shape of FIG. 5 may be identically applied to regions other than the region C only from the descriptions of FIGS. 1, 3, and 5.

As shown in FIG. 5, the trench formed in the pixel-defining layer 106 may have a bottom surface that is concave downward. In addition, the top surface of the pixel-defining layer 106 between the trenches may be convex upward. Such curves or curved surfaces may be a feature generated by a wet etching process. For example, the embodiment of FIG. 4 may be an example of at least one trench formed through a dry etching process and the embodiment of FIG. 5 may be an example of at least one trench formed through a wet etching process.

For example, the trenches formed in the pixel-defining layer 106 may be arranged closer to the reference surface (the bottom surface of the pixel-defining layer 106 or the top surface of the substrate 100) as the farther away the trenches are from the spacer SPC, based on the bottom surface of the pixel-defining layer 106 or the top surface of the substrate 100. Accordingly, the distance d1 between the bottom surface of the first trench TR1 and the bottom surface of the pixel-defining layer 106 may be the greatest.

For example, the at least one trench may include a plurality of trenches. The pixel-defining layer 106 may include the first trench TR1 adjacent to the spacer SPC and the second trench TR2 provided between the first pixel electrode 140a and the first trench TR1. The distance d1 between the bottom surface of the first trench TR1 and the bottom surface of the pixel-defining layer 106 may be greater than the distance d2 between the bottom surface of the second trench TR2 and the bottom surface of the pixel-defining layer 106. The distance d2 between the bottom surface of the second trench TR2 and the pixel-defining layer 106 may be greater than the distance d3 between the bottom surface of the third trench TR3 and the pixel-defining layer 106.

As shown in FIG. 5, the curved trench formed through the wet etching process may naturally induce flow of the filler 800 to trap the filler 800 in the trench. Accordingly, spreading of the filler 800 may be reduced and a possibility of the filler 800 being introduced to the pixel region may be reduced.

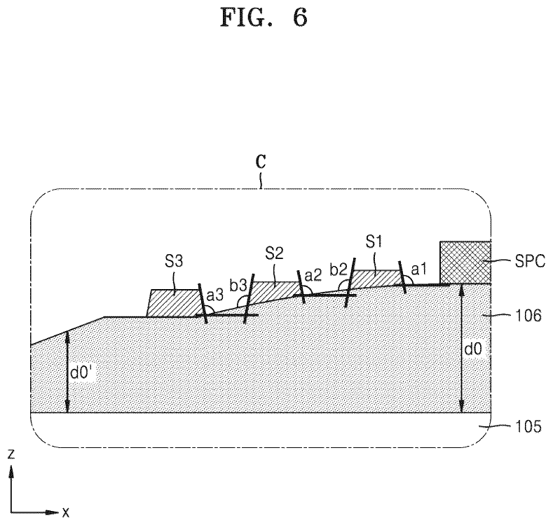

FIG. 6 is a cross-sectional view of a region C of FIG. 3, according to an embodiment.

For reference, while describing FIG. 6, details that are the same as or overlap those above may be omitted. For convenience of description, an example of the region C is described, but in light of this disclosure one of ordinary skill in the art will understand that a shape of FIG. 6 may be identically applied to regions other than the region C only from the descriptions of FIGS. 1, 3, and 6.

As shown in FIG. 6, the same effects as the trench described above may be achieved by using a protrusion separately formed on the pixel-defining layer 106 instead of the trench formed through an etching process.

For example, the display apparatus according to an embodiment may include at least one protrusion disposed on the pixel-defining layer 106 of FIG. 6. The at least one protrusion may be a component replacing the at least one trench described above. The protrusion may be formed on the pixel-defining layer 106 instead of the trench being formed on the pixel-defining layer 106.

The at least one protrusion may be arranged around the spacer SPC in a plan view. The at least one protrusion may be provided between the spacer SPC and the first pixel electrode 140a in a plan view, and angles a1, a2, a3, b2, and b3 between an outer surface of the at least one protrusion and the top surface of the substrate 100 may be more than 90°. The angles a1, a2, a3, b2, and b3 between the outer surface of the at least one protrusion and the top surface of the substrate 100 may be angles measured outside the at least one protrusion.

The at least one protrusion may include a plurality of protrusions. The plurality of protrusions may include a first protrusion S1 adjacent to the spacer SPC and a second protrusion S2 provided between the first pixel electrode 140a and the first protrusion S1.

The thicknesses d0 and d0′ of the pixel-defining layer 106 may decrease towards the first pixel electrode 140a, based on the spacer SPC. For example, the thicknesses d0 and d0′ of the pixel-defining layer 106 may increase towards the spacer SPC.

The first protrusion S1 may surround, in the shape of “□”, the spacer SPC in a plan view. The second protrusion S2 may surround, in the shape of “□”, the first protrusion S1 in a plan view.

The plurality of protrusions may further include a third protrusion S3 adjacent to the second protrusion S2. The at least one protrusion may further include the third protrusion S3 provided between the second protrusion S2 and the first pixel electrode 140a in a plan view.

The plurality of protrusions may further include a third′ protrusion adjacent to the second protrusion S2. The at least one protrusion may further include the third′ protrusion provided between the second protrusion S2 and the second pixel electrode 140b in a plan view.

The first pixel electrode 140a and the second pixel electrode 140b may be spaced apart from each other in the first direction in a plan view, and the third protrusion S3 and the third′ protrusion may extend in the second direction crossing the first direction.

Portions of the first protrusion S1 and second protrusion S2 may extend in the second direction. For example, a portion of the first protrusion S1 in the shape of “□”, which is provided between the first pixel electrode 140a and the spacer SPC in a plan view, may extend in the second direction, and a portion of the first protrusion S1 in the shape of “□”, which is provided between the second pixel electrode 140b and the spacer SPC in a plan view, may extend in the second direction.

Portions of the first protrusion S1 and second protrusion S2 may extend in the first direction. For example, a portion of the first protrusion S1 in the shape of “□”, which is provided between the third pixel electrode and the spacer SPC in a plan view, may extend in the first direction, and a portion of the first protrusion S1 in the shape of “□”, which is provided between the fourth pixel electrode and the spacer SPC in a plan view, may extend in the first direction.

As shown in FIG. 6, a structure using the first protrusion S1, the second protrusion S3, and the third protrusion S3 may provide similar effects as a trench while increasing flexibility of a manufacturing process. A protrusion may be further precisely manufactured, and thus, by adjusting a height of the protrusion, a width of the protrusion, and the like, a filler blocking effect may be optimized.

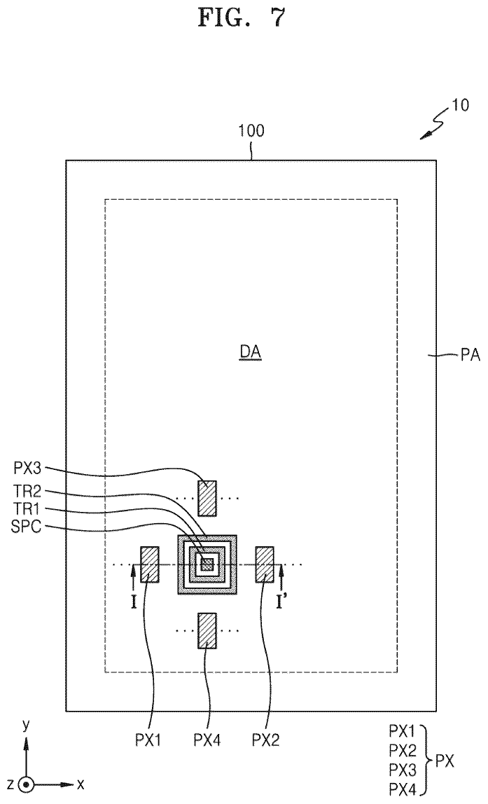

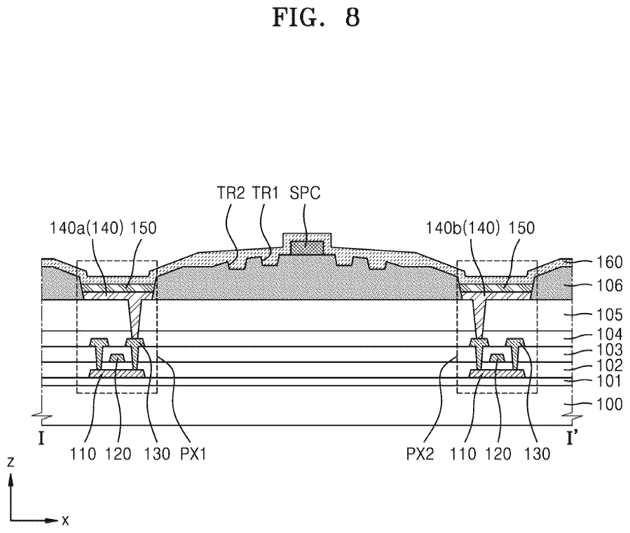

FIG. 7 is a plan view schematically showing a display apparatus according to an embodiment, and FIG. 8 is a cross-sectional view of the display apparatus taken along line I-I′ of FIG. 7, according to an embodiment.

For reference, while describing FIGS. 7 and 8, details that are the same as or overlap those above may be omitted. Also, technical ideas about the trench of FIGS. 7 and 8 may be replaced by technical ideas about the protrusion described above.

As shown in FIGS. 7 and 8, at least one trench provided around the spacer SPC may be variously modified. For example, the third trench TR3 and the third′ trench TR3′ described above may be omitted depending on a distance between pixel electrodes.

By adjusting the number and arrangements of trenches according to a distance between pixels, a filler blocking structure optimized according to the resolution or structure of the display panel 10 may be provided. According to the optimized filler blocking structure, structural flexibility of being applicable to various products may be provided.

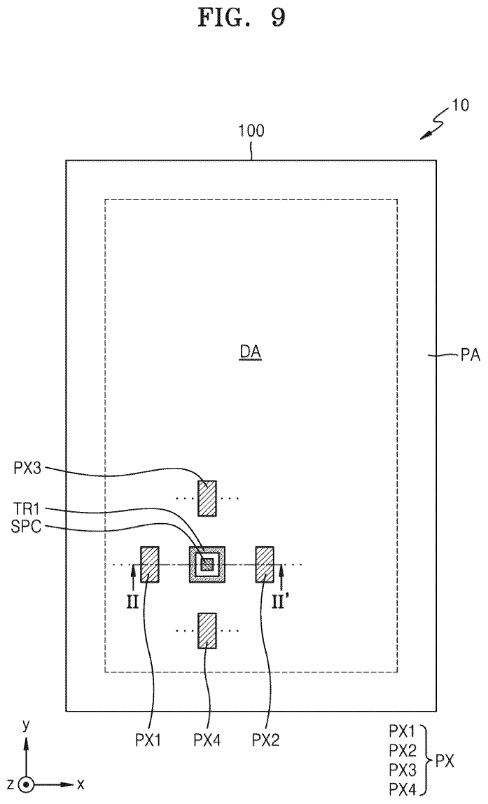

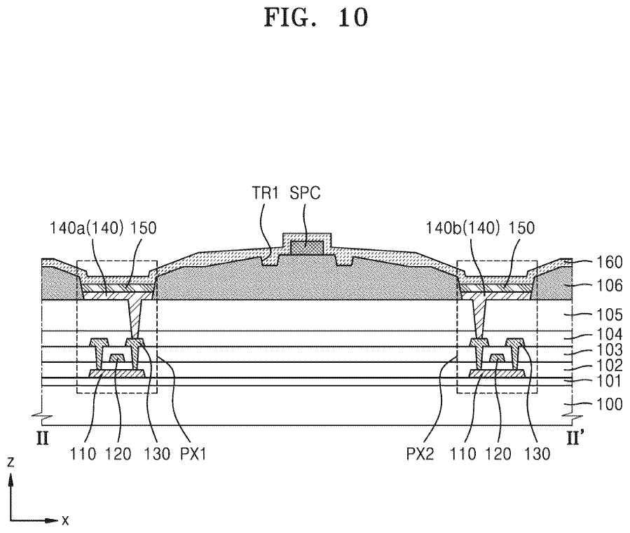

FIG. 9 is a plan view schematically showing a display apparatus according to an embodiment, and FIG. 10 is a cross-sectional view of the display apparatus taken along line II-II′ of FIG. 9, according to an embodiment.

For reference, while describing FIGS. 9 and 10, details that are the same as or overlap those above may be omitted. Also, technical ideas about the trench of FIGS. 9 and 10 may be replaced by technical ideas about the protrusion described above.

As shown in FIGS. 9 and 10, at least one trench provided around the spacer SPC may be variously modified. For example, not only the third trench TR3 and the third′ trench TR3′ described above, but also the second trench TR2 may be omitted depending on a distance between pixel electrodes.

As such, by reducing the number of trenches while providing an effective filler blocking structure, a manufacturing process may be simplified and productivity may be improved.

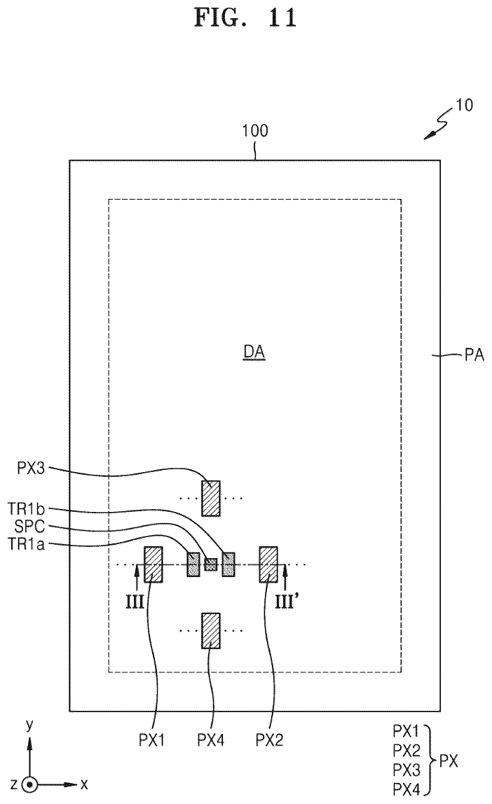

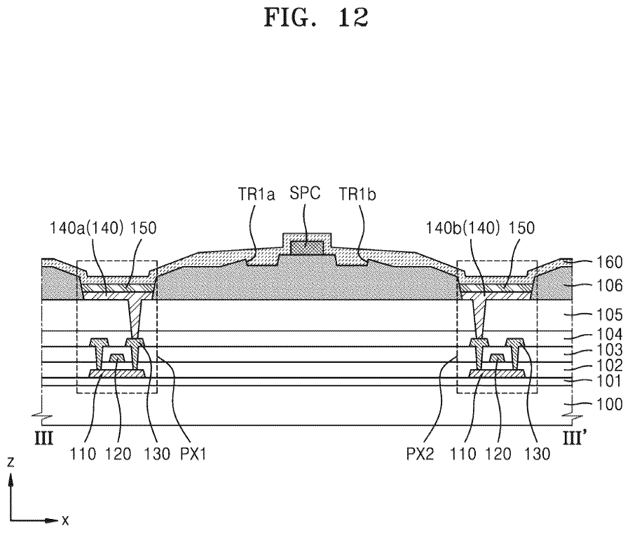

FIG. 11 is a plan view schematically showing a display apparatus according to an embodiment, and FIG. 12 is a cross-sectional view of the display apparatus taken along line III-III′ of FIG. 11, according to an embodiment.

For reference, while describing FIGS. 11 and 12, details that are the same as or overlap those above may be omitted. Also, technical ideas about the trench of FIGS. 11 and 12 may be replaced by technical ideas about the protrusion described above.

As shown in FIGS. 11 and 12, a first-1 trench TR1a may be provided between the spacer SPC and the first pixel electrode 140a in a plan view. The first-1 trench TR1a may be formed on the pixel-defining layer 106, wherein a width of the first-1 trench TR1a in the x-axis direction may be greater than a width of the first trench TR1 of FIGS. 1, 7, and 9 in the x-axis direction. As such, a width of a trench formed in the pixel-defining layer 106 may be variously modified.

A first-2 trench TR1b may be provided between the spacer SPC and the second pixel electrode 140b in a plan view. The first-2 trench TR1b may be formed in the pixel-defining layer 106, wherein a width of the first-2 trench TR1b in the x-axis direction may be greater than the width of the first trench TR1 of FIGS. 1, 7, and 9 in the x-axis direction. As such, a width of a trench formed in the pixel-defining layer 106 may be variously modified.

The first-1 trench TR1a may extend in the second direction and the first-2 trench TR1b may extend in the second direction.

As such, by increasing a width of a trench, a larger amount of fillers may be accommodated, thereby improving long-term reliability. In particular, a structure more robust to filler leakage that may occur during a life cycle of a product may be provided.

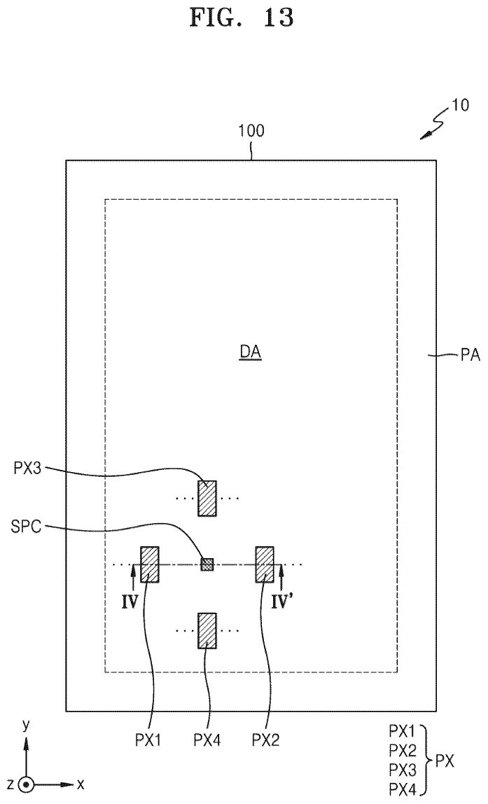

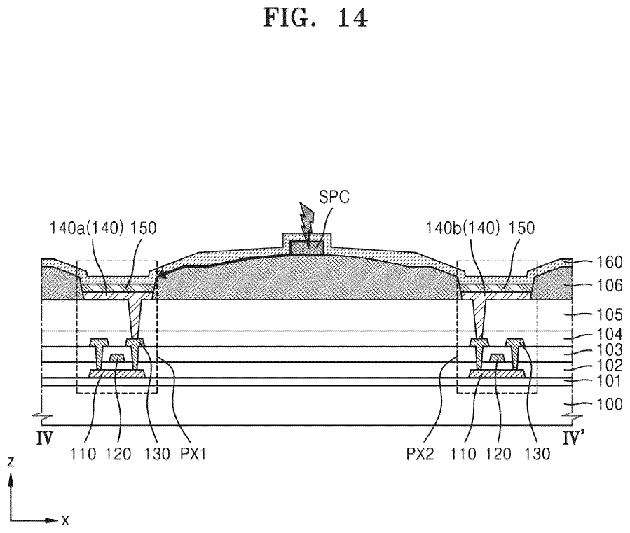

FIG. 13 is a plan view schematically showing a display apparatus according to Comparative Example, and FIG. 14 is a cross-sectional view of the display apparatus taken along line IV-IV′ of FIG. 13.

For reference, while describing FIGS. 13 and 14, details that are the same as or overlap those above may be omitted.

As shown in FIGS. 13 and 14, a trench is not formed in the pixel-defining layer 106 included in the display apparatus according to Comparative Example. When a trench is not formed, the filler 800 introduced through a crack generated in the spacer SPC may flow to a pixel. When the filler 800 flows to the pixel, brightness of the pixel may be affected. Accordingly, a defect rate of the display apparatus may be noticeably increased.

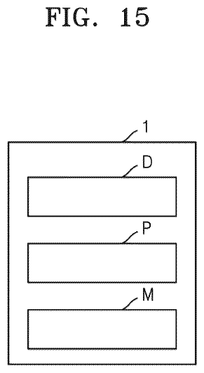

FIG. 15 is a conceptual view schematically showing an electronic device 1 including the display apparatus of FIG. 1. For convenience of description, while describing FIG. 15, details that are the same as or overlap those above may be omitted.

As shown in FIG. 15, the electronic device 1 according to an embodiment may include a mobile phone, a tablet PC, a laptop PC, or a smart watch or smart band worn on a wrist. The electronic device 1 may be a term encompassing various products, such as home appliances, computing devices, and portable electronic devices, which use a display apparatus D.

The electronic device 1 may include a memory M storing instructions, a processor P configured to operate the instructions stored in the memory M to generate a control command, and the display apparatus D configured to display an image based on the control command generated by the processor P.

The display apparatus D included in the electronic device 1 may be any one of the display apparatuses described with reference to FIGS. 1 to 14.

The processor P included in the electronic device 1 may control other components by executing the instructions stored in the memory M. The processor P may perform the instructions stored in the memory M.

The processor P is a component that may perform an operation and control another device. Mainly, the processor P may denote a microprocessor, a central processing unit, an application processor, or a graphics processing unit.

The processor P may process a signal, data, or information input or output through components described above, or drive an application program stored in the memory M, thereby providing suitable information or function to a user or processing the same.

The memory M included in the electronic device 1 stores pieces of data supporting various functions of the electronic device 1. The memory M may store various application programs (or applications) driven by the electronic device 1 and pieces of data and instructions for operations of the electronic device 1.

The memory M may include at least one type of storage medium from among a flash memory type, a hard disk type, a solid state disk (SSD) type, a silicon disk drive (SDD) type, a multimedia card micro type, or card-type memory (e.g., a secure digital or extreme digital (XD) memory), random access memory (RAM), static RAM (SRAM), read-only memory (ROM), electrically erasable programmable ROM (EEPROM), programmable ROM (PROM), a magnetic memory, a magnetic disk, and an optical disk.

According to an embodiment, an electronic device may include a memory storing instructions, a processor configured to operate the instructions to generate a control command, and a display apparatus configured to display an image based on the control command. The display apparatus may include the substrate 100, the first pixel electrode 140a and the second pixel electrode 140b disposed on the substrate 100, the pixel-defining layer 106 disposed on the substrate 100 and covering the edges of the first pixel electrode 140a and the second pixel electrode 140b, and the spacer SPC disposed on the pixel-defining layer 106 and provided between the first pixel electrode 140a and the second pixel electrode 140b in a plan view.

For example, the pixel-defining layer 106 may include at least one trench provided between the spacer SPC and the first pixel electrode 140a in a plan view. An angle between an inner surface of the at least one trench and a bottom surface of the at least one trench may be more than 90°. The display apparatus D of FIG. 15 may be the display apparatus of FIGS. 1 to 14 described above.

According to an embodiment, a display apparatus in which a defect rate is reduced and an electronic device including the same may be realized. The scope of the disclosure is not limited by such effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a first pixel electrode and a second pixel electrode, which are disposed on the substrate;
a pixel-defining layer disposed on the substrate and covering edges of the first pixel electrode and second pixel electrode; and
a spacer disposed on the pixel-defining layer and provided between the first pixel electrode and the second pixel electrode in a plan view,
wherein the pixel-defining layer comprises at least one trench provided between the spacer and the first pixel electrode in a plan view and
an angle between an inner surface of the at least one trench and a bottom surface of the at least one trench is more than 90°.

2. The display apparatus of claim 1, wherein the pixel-defining layer comprises a first trench adjacent to the spacer and a second trench provided between the first pixel electrode and the first trench.

3. The display apparatus of claim 2, wherein a distance between a bottom surface of the first trench and a bottom surface of the pixel-defining layer is greater than a distance between a bottom surface of the second trench and the bottom surface of the pixel-defining layer.

4. The display apparatus of claim 2, wherein the pixel-defining layer further comprises a third trench provided between the second trench and the first pixel electrode in a plan view.

5. The display apparatus of claim 4, wherein a distance between a bottom surface of the second trench and a bottom surface of the pixel-defining layer is greater than a distance between a bottom surface of the third trench and the bottom surface of the pixel-defining layer.

6. The display apparatus of claim 2, wherein the first trench surrounds, in a shape of “□”, the spacer in a plan view.

7. The display apparatus of claim 6, wherein the second trench surrounds, in a shape of “□”, the first trench in a plan view.

8. The display apparatus of claim 7, wherein the pixel-defining layer further comprises a third trench provided between the second trench and the first pixel electrode, and a third′ trench provided between the second trench and the second pixel electrode, in a plan view.

9. The display apparatus of claim 1, wherein the first pixel electrode and the second pixel electrode are spaced apart from each other in a first direction in a plan view.

10. The display apparatus of claim 9, wherein at least a portion of the at least one trench extends in a second direction crossing the first direction in a plan view.

11. A display apparatus comprising:
a substrate;
a first pixel electrode and a second pixel electrode, which are disposed on the substrate;
a pixel-defining layer disposed on the substrate and covering edges of the first pixel electrode and second pixel electrode;
a spacer disposed on the pixel-defining layer and provided between the first pixel electrode and the second pixel electrode in a plan view; and
at least one protrusion disposed on the pixel-defining layer and arranged around the spacer in a plan view,
wherein the at least one protrusion is provided between the spacer and the first pixel electrode in a plan view and
an angle between an outer surface of the at least one protrusion and a top surface of the substrate is more than 90°.

12. The display apparatus of claim 11, wherein the at least one protrusion comprises a first protrusion adjacent to the spacer and a second protrusion provided between the first pixel electrode and the first protrusion.

13. The display apparatus of claim 11, wherein a thickness of the pixel-defining layer decreases towards the first pixel electrode away from the spacer.

14. The display apparatus of claim 12, wherein the at least one protrusion further comprises a third protrusion provided between the second protrusion and the first pixel electrode in a plan view.

15. The display apparatus of claim 14, wherein the first protrusion surrounds, in a shape of “□”, the spacer in a plan view.

16. The display apparatus of claim 15, wherein the second protrusion surrounds, in a shape of “□”, the first protrusion in a plan view.

17. The display apparatus of claim 16, wherein the at least one protrusion further comprises a third′ protrusion provided between the second protrusion and the second pixel electrode in a plan view.

18. The display apparatus of claim 11, wherein the first pixel electrode and the second pixel electrode are spaced apart from each other in a first direction in a plan view.

19. The display apparatus of claim 18, wherein at least a portion of the at least one protrusion extends in a second direction crossing the first direction in a plan view.

20. An electronic device comprising:
a memory storing instructions;
a processor configured to operate the instructions to generate a control command; and
a display apparatus configured to display an image based on the control command,
wherein the display apparatus comprises:
a substrate;
a first pixel electrode and a second pixel electrode, which are disposed on the substrate;
a pixel-defining layer disposed on the substrate and covering edges of the first pixel electrode and second pixel electrode; and
a spacer disposed on the pixel-defining layer and provided between the first pixel electrode and the second pixel electrode in a plan view,
wherein the pixel-defining layer comprises at least one trench provided between the spacer and the first pixel electrode in a plan view and
an angle between an inner surface of the at least one trench and a bottom surface of the at least one trench is more than 90°.
